(19) United States
(12) Patent Application Publication
(10) Pub. No.: US 2006/0023763 A1
(43) Pub. Date: Feb. 2, 2006

(54) Semiconductor lasers with hybrid materials systems

(75) Inventors: Jason Nathaniel Farmer, Vancouver, WA (US); Mark Andrew DeVito, Vancouver, WA (US); Zhe Huang, Vancouver, WA (US); Paul Andrew Crump, Portland, OR (US); Michael Peter Grimshaw, Vancouver, WA (US); Prabhuram Thiagarajan, Camas, WA (US); Weimin Dong, Vancouver, WA (US); Jun Wang, Vancouver, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 10/902,224

(22) Filed: Jul. 28, 2004

(51) Int. Cl. H01S 5/00

(52) U.S. Cl. 372/45.01; 372/46.01

(57) ABSTRACT

A semiconductor laser and a method of forming the same are provided. The semiconductor laser includes cladding layers comprised of hybrid materials systems which have different conduction to valance band gap offset ratios with respect to GaAs. As a result of these hybrid structures, lower junction voltages on both the n-side and p-side of the laser structure are achieved, thereby increasing the electrical to optical conversion efficiency of the laser.

### REFERENCE TO GOVERNMENT CONTRACT

This invention was made with U.S. Government support under Grant No. MDA972-03-C-0101 awarded by DARPA. The United States Government has certain rights in this invention.

### FIELD OF THE INVENTION

The present invention relates generally to semiconductor lasers.

### BACKGROUND OF THE INVENTION

High power diode lasers have been widely used in industrial, graphics, medical and defense applications. Power level, reliability and electrical to optical conversion efficiency are the most important parameters for these lasers with conversion efficiency being of fundamental importance. High electrical to optical conversion efficiency not only saves energy, but is also a means of improving device power level and reliability. The higher the conversion efficiency, the higher the output power that can be achieved for a given input power level. Furthermore, with higher efficiencies there is less heat waste, leading to lower junction temperatures and longer achievable lifetimes.

A diode laser's electrical to optical conversion efficiency is defined as the percentage of output power to input electrical power, the input power being a product of input current and voltage. Therefore lowering a diode laser's operational voltage while maintaining good threshold current and slope efficiency is critical to the electrical to optical conversion efficiency as well as to the output power level and reliability as mentioned above.

A semiconductor material is characterized by band structures, i.e., conduction bands and valence bands. Electron energy is associated with the conduction band while hole energy is associated with the valence band. The energy difference between the two bands is called the energy band gap or the band gap energy. When two layers of different compositions, or band gap energies, are joined together, the band gap energy difference between the layers will be split into a conduction band offset and a valence band offset, with the ratio being determined by the materials systems. For example, the conduction band to valance band offset ratio is about 60/40 for the AlGaAs/GaAs system, while the ratio is about 35/65 for the InGaP/GaAs, AlGaInP/GaAs and InGaAsP/GaAs systems.

A diode laser contains multiple layers which have different band gap energies, doping types and levels. When current is supplied to a diode laser, electrons and holes are injected into the diode from the n-side and p-side contact layers, respectively, the electrons and holes passing through the various layers (e.g., cladding and confinement layers) to the active region, where they combine and generate photons, or light.

Conventional diode laser structures operating in the wavelength range of 700 nm to 1150 nm typically employ AlGaAs-based or InGaAsP-based systems grown on GaAs substrates. In some high power laser structures, different materials systems may be used in the cladding layers and the confinement layers. In all prior structures, however, the n-side and p-side cladding layers are selected from the same materials system. As a result, these structures do not favor both electron and hole transporting to the active region. For example, assuming a structure in which AlGaAs is used for both the n- and p-cladding layers, the high conduction band offset with respect to GaAs, near 60% of the total band gap offset, will require excess voltage for electron transport to the active region. In the same structure the valence band offset, near 40% of the total band gap, favors hole transporting. Similarly in a structure in which (Al)InGa(As)P is used for both the n- and p-cladding layers, the high valance band offset (i.e., near 65% of the total offset) will require excess voltage for hole transport to the active region even though the conduction band offset (i.e., near 35% of the total offset) is in favor of electron transporting.

Accordingly, what is needed in the art is a diode laser structure that is optimized for both the n-side and p-side junctions, thus leading to lower operational voltages and improved electrical to optical conversion efficiencies. The present invention provides such a structure.

### SUMMARY OF THE INVENTION

The present invention provides hybrid materials systems for the n-cladding and p-cladding layers of laser diode structures. The materials system of the n-side cladding layer is selected from the group that has a small conduction to valance band gap offset ratio while the materials system of the p-side cladding layer is selected from the group that has a large conduction to valance band gap offset ratio, both offsets being given with respect to GaAs. As a result of these hybrid materials systems, the transport of electrons and holes to the active region requires lower junction voltages, thus leading to lower operational voltages and higher electrical to optical conversion efficiencies.

In one embodiment of the invention, a diode laser operating in the wavelength range of 900 to 1100 nm is fabricated in which AlGaAs is used for the p-cladding layer. InGaP, AlGaInP or GaInAsP is used for the n-cladding layer. The confinement layers are comprised of AlGaAs or GaInAsP. The substrate is preferably comprised of n-type GaAs, although the substrate can also be comprised of p-type GaAs, undoped GaAs, n-type InGaAs, p-type InGaAs or undoped InGaAs.

Another aspect of the invention is a method of fabricating a diode laser structure utilizing hybrid materials systems. In one embodiment, a broad area semiconductor diode laser is grown using MOCVD and fabricated using photolithographic techniques, ion implantation, p-metal metallization, lapping and polishing, n-metallization, bar cleaving, facet coating and die bonding. An exemplary broad area diode laser achieved an electrical to optical conversion efficiency of greater than 60%.

In another aspect of the invention, semiconductor diode lasers employing hybrid materials systems in the cladding layers are fabricated that operate within the wavelength range of 600 to 1600 nanometers. In these diode lasers, the composition and thickness of the active region is varied.

A further understanding of the nature and advantages of the present invention may be realized by reference to the remaining portions of the specification and the drawings.

### BRIEF DESCRIPTION OF THE DRAWINGS

FIG. 1 is a schematic band diagram for a particular embodiment of the invention;

FIG. 2 is an illustration of an exemplary epitaxial structure fabricated in accordance with the invention;

FIG. 3 is an illustration of a broad area laser fabricated using the epitaxial structure of FIG. 2;

FIG. 4 is a graphical illustration of the light output power and voltage versus current for devices fabricated in accordance with the invention; and

FIG. 5 is a graphical illustration of the light output power and conversion efficiency versus current for devices fabricated in accordance with the invention; and

FIG. 6 is an illustration of a second exemplary epitaxial structure fabricated in accordance with the invention.

### DESCRIPTION OF THE SPECIFIC EMBODIMENTS

According to the present invention, the n-side and p-side cladding layers of a semiconductor diode laser are comprised of hybrid materials systems such that the n-side cladding layer has a small conduction to valance band gap offset ratio and the p-side cladding layer has a large conduction to valance band gap offset ratio. As a result of these hybrid materials layers, the device requires lower junction voltages, leading to lower operational voltages and higher electrical to optical conversion efficiencies.

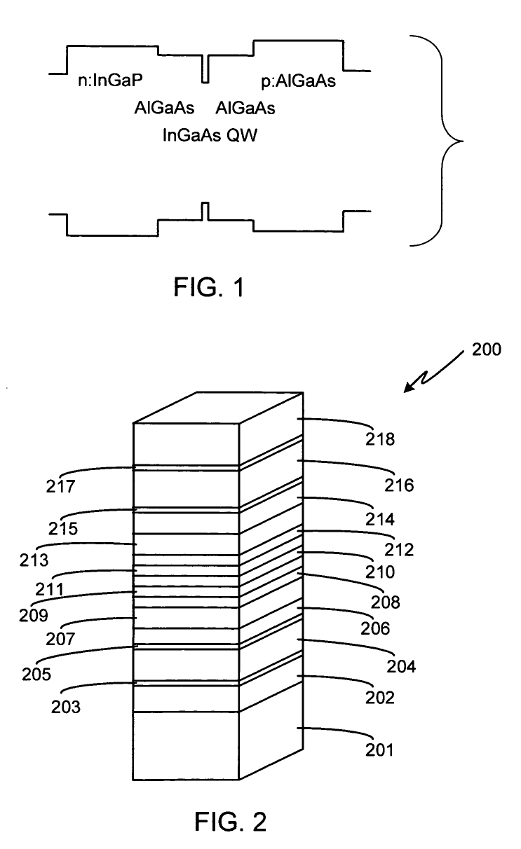

FIG. 1 is a schematic band diagram for a particular embodiment of the invention. The exemplary diagram of FIG. 1 is for a structure comprised of a GaAs substrate, InGaAs quantum well, AlGaAs confinement layers, InGaP n-side cladding layer and AlGaAs p-side cladding layer.

FIG. 2 is an example of an epitaxial structure 200 fabricated in accordance with the invention. It should be understood that this structure is only meant to illustrate the improvements achievable through use of the hybrid materials layers of the invention and that variations of this structure are clearly envisioned by the inventors.

Substrate 201 is fabricated from Si-doped, n+ type GaAs material. Other substrates suitable for use with the invention include p-type GaAs, undoped GaAs, n-type InGaAs, p-type InGaAs and undoped InGaAs. After substrate 201 is degassed and deoxided, an n-type GaAs buffer layer 202 is grown in order to recondition the surface of substrate 201. The thickness of buffer layer 202 is within the range of 0.05 to 10 microns, preferably within the range of 0.1 to 1 micron, and more preferably 0.5 microns. Buffer layer 202 can also be comprised of InGaAs, the choice of material primarily driven by the material selected for substrate 201.

A transition layer 203 is grown on top of buffer layer 202. In the illustrated embodiment, transition layer 203 is 0.04 microns thick and comprised of Si-doped AlGaAs with the composition ramping from 5% to 25%. The n-side cladding layer 204 is preferably comprised of InGaP, although it can also be comprised of InGaAsP or AlGaInP. The thickness of cladding layer 204 is within the range of 0.5 to 5 microns, preferably within the range of 1 to 3 micron, and more preferably 2 microns. Cladding layer 204 can utilize either a graded or constant doping level although a constant doping level is preferred. The doping level is within the range of 0.3×10¹⁸ cm⁻³ to 3×10¹⁸ cm⁻³, preferably within the range of 0.5×10¹⁸ cm⁻³ to 2×10¹⁸ cm⁻³, and more preferably approximately 1×10¹⁸ cm⁻³.

After the n-side cladding layer 204, a Si-doped AlGaAs transition layer 205 is grown with a composition ramping from 25% to 20%. The thickness of transition layer 205 is within the range of 0 to 0.5 microns, preferably within the range of 0.01 to 0.1 microns, and more preferably 0.05 microns. Preferably transition layer 205 is doped at the same level as n-side cladding layer 204.

The next layers in the structure are a pair of confinement layers 206 and 207, one or both of which are comprised of AlGaAs or InGaAsP, and preferably in which both are comprised of AlGaAs with an Al content within the range of 10% to 35%, preferably within the range of 10% to 25%, and more preferably 20%. The thickness of confinement layer 206 is within the range of 0 to 1 microns, preferably within the range of 0 to 0.6 microns, and more preferably 0.15 microns. The doping level is within the range of 0 to 2×10¹⁸ cm⁻³, preferably within the range of 0 to 1×10¹⁸ cm⁻³, and more preferably approximately 3×10¹⁷ cm⁻³. In the preferred embodiment confinement layer 206 is doped with Si. The thickness of confinement layer 207 is within the range of 0 to 1 microns, preferably within the range of 0 to 0.6 microns, and more preferably 0.25 microns. Confinement layer 207 can be lightly doped up to 5×10¹⁷ cm⁻³ with either n-type or p-type dopant, although in the preferred embodiment layer 207 is undoped. A graded index layer 208 comprised of AlGaAs is grown on top of layer 207. The Al content in layer 208 ramps from x % to y %, where x and y are both in the range of 10% to 35% and the y value is less than the x value. Preferably the x value is equal to or less than the Al content in layer 207. In the preferred embodiment, the x value is 20% and the y value is 10%. The thickness of graded index layer 208 is within the range of 0 to 0.5 microns, preferably within the range of 0 to 0.2 microns, and more preferably 0.1 microns. Graded index layer 208 can be lightly doped up to 5×10¹⁷ cm⁻³ with either n-type or p-type dopant, although in the preferred embodiment layer 208 is undoped.

Layers 209-211 represent the active region of the diode laser. In the preferred embodiment layers 209 and 211 (e.g., barrier layers) are comprised of GaAs. Layers 209 and 211 can also be fabricated from AlGaAs with an Al content in the range of 0% to 35%, and preferably within the range of 0% to 20%. Layer 210 is a quantum well layer which, in this embodiment, is comprised of InGaAs with an indium content approximately 14% and a thickness of approximately 70 angstroms, thus achieving a laser wavelength of approximately 940 nanometers. The In content and the thickness of quantum well layer 210 can be varied in order to achieve different wavelengths. Wavelength selection can also be achieved by adding various elements such as aluminum, antimony, nitrogen, phosphorus and other III-V elements to the quantum well layer.

Layer 212 is the p-side graded index layer comprised of AlGaAs. The Al content in layer 212 ramps from a % to b %, where a and b are both in the range of 5% to 35% and the a value is less than the b value. Preferably the b value is equal to or less than the Al content in layer 213. In the preferred embodiment, the a value is 10% and the b value is 30%. The thickness of graded index layer 212 is within the range of 0 to 1 microns, preferably within the range of 0 to 0.2 microns, and more preferably 0.05 microns.

Layers 213 and 214 are a pair of p-side confinement layers, one or both of which are comprised of AlGaAs or InGaAsP, and preferably in which both are comprised of AlGaAs with an Al content within the range of 10% to 45%, preferably within the range of 10% to 35%, and more preferably 30%. The thickness of confinement layer 213 is within the range of 0 to 1 microns, preferably within the range of 0 to 0.6 microns, and more preferably 0.25 microns. Confinement layer 213 can be lightly doped up to 5×10¹⁷ cm⁻³ with either n-type or p-type dopant, although in the preferred embodiment layer 213 is undoped. The thickness of confinement layer 214 is within the range of 0 to 1 microns, preferably within the range of 0 to 0.6 microns, and more preferably 0.15 microns. The doping of layer 214 is within the range of 0 to 2×10¹⁸ cm⁻³, preferably within the range of 0 to 1×10¹⁸ cm⁻³, and more preferably approximately 3×10¹⁷ cm⁻³. In the preferred embodiment layer 214 is doped with Zn.

Before growing the p-cladding layer 216, a p-type doped transition layer 215 with Al composition ramping from that of layer 214 to that of layer 216 is grown. The thickness of the layer 215 is within the range of 0 to 0.5 microns, preferably within the range of 0.01 to 0.1 microns, and more preferably 0.05 microns. Transition layer 215 is doped at the same level and type as p-cladding layer 216. In the preferred embodiment layers 215 and 216 are doped with Zn. The growth of p-cladding layer 216 continues from the growth of transition layer 215. The thickness of p-cladding layer 216 is within the range of 0.5 to 3 microns, preferably within the range of 0.7 to 1.5 microns, and more preferably 1 micron. The doping level of layer 216 is within the range of 0.3×10¹⁸ cm⁻³ to 3×10¹⁸ cm⁻³, preferably within the range of 0.5×10¹⁸ cm⁻³ to 1.5×10¹⁸ cm⁻³, and more preferably approximately 1×10¹⁸ cm⁻³. P-cladding layer 216 is fabricated from AlGaAs with an Al content within the range of 5% to 100%. A short transition layer 217 is grown after the p-cladding layer 216 to ramp down the Al content from that of layer 216 to a lower value, the lower value being 5% in the preferred embodiment. The last layer of structure 200 is GaAs contact layer 218. The thickness of contact layer 216 is within the range of 0.05 to 3 microns, preferably within the range of 0.07 to 1 micron, and more preferably 0.3 microns. In the preferred embodiment contact layer 218 is doped to a level of 1×10²⁰ cm⁻³.

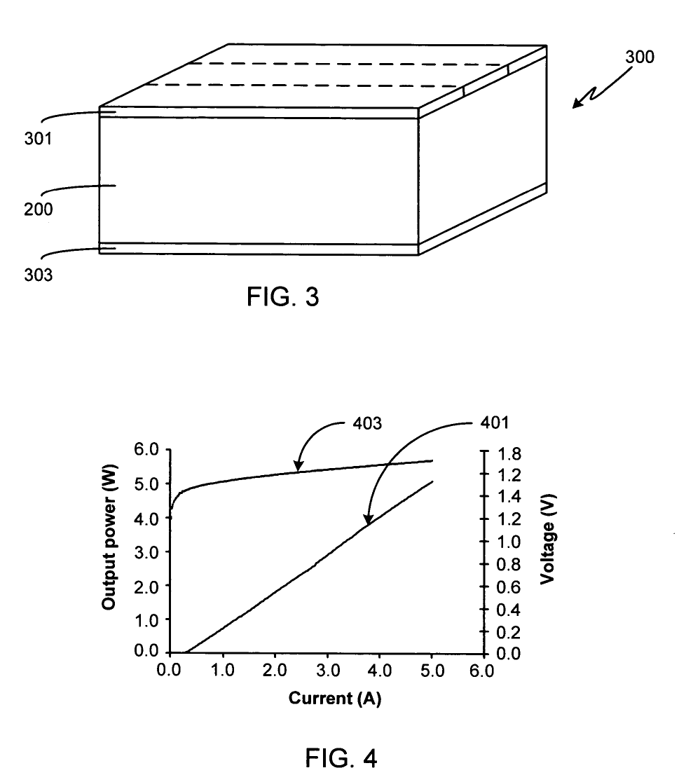

Using epitaxial structure 200, broad area lasers 300 were fabricated with 150 micron wide stripe widths and 500 micron emitter to emitter pitches (FIG. 3). The p-metal layer 301 is comprised of Ti, Pt and Au. The substrates were thinned down to a thickness of about 140 microns by lapping and polishing, followed by n-metal layer 303 evaporation on the backsides of the wafers. After n-side metallization, the wafers were cleaved into 1 millimeter long bars and coated to nominal reflectivities of 5% and 95% for the front and rear facets, respectively. After facet coating, the bars were diced into individual chips. The chips were then bonded onto copper heat sinks with the p-n junction down using indium solder and wired to electrical connection pads using an automatic wire bonder.

Device testing was carried out on a test station under CW conditions with the copper heat sink mounted to a cold plate at a temperature of 25° C. during testing. Device output power and voltage were measured with a calibrated integration sphere and a digital multi-meter, respectively.

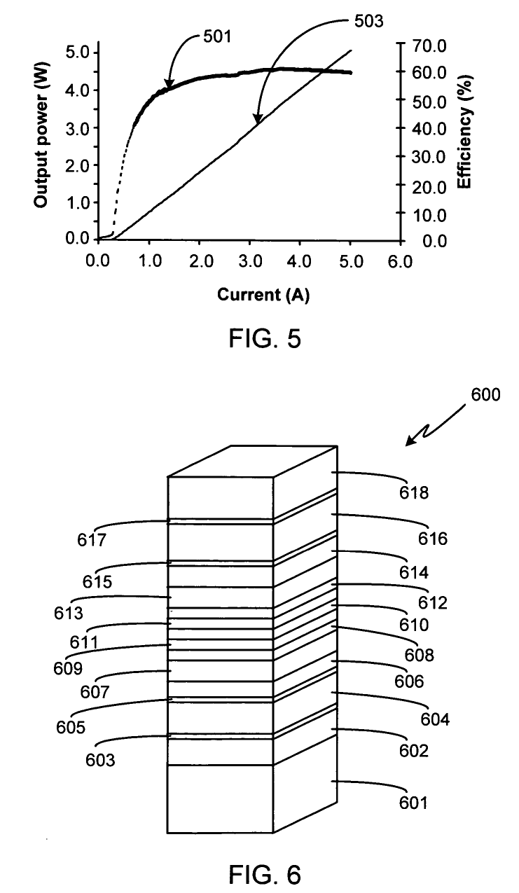

FIG. 4 graphically illustrates typical curves of light output power (curve 401) and voltage (curve 403) versus current for a laser chip fabricated in accordance with the invention. The device has a threshold current of 290 mA, or equivalent threshold current density of 193 A/cm². The device's slope efficiency is about 1 W/A. The device reaches an output of 4 W at a current of slightly less than 4A. At 4A the device's operational voltage is about 1.67V. Near 4A the device's differential resistance is about 0.03 Ohms. FIG. 5 graphically illustrates typical curves of electrical to optical efficiency (curve 501) and light output power (curve 503) versus current for a laser chip fabricated in accordance with the invention. As shown in FIG. 5, the device's efficiencies are above 60% for currents from 3.1 A to 4.5 A, or output power from 3.0 W to 4.6 W. The peak efficiency of the device is about 60.7% near 3.6 A or 3.7 W. Spectrum measurements indicated that the device's operating wavelength is near 940 nm.

To compare the performance of a device fabricated in accordance with the invention and one fabricated in accordance with the prior art, devices were fabricated identical to the structure described in detail above, except that the n-cladding layer was replaced with a conventional AlGaAs layer. Although the prior art based device had similar threshold current and slope efficiency to the previously described embodiment of the invention, the highest peak efficiency of the prior art based device was only 53% with an operational voltage of about 1.78V at 4A.

The diode laser with hybrid cladding layers described in detail above was grown by a metal organic chemical vapor phase epitaxy (MOCVD) in a commercial planetary reactor operating at low pressure. It will be understood by those of skill in the art that other epitaxial growth techniques can also be used to fabricate the same or similar structures, such techniques including, but not limited to, molecular beam epitaxy (MBE), gas source molecular beam epitaxy (GSMBE), chemical beam epitaxy (CBE), metal organic molecular beam epitaxy (MOMBE) and liquid phase epitaxy (LPE).

It will be understood that the detailed device structure is an exemplary embodiment and is not intended to limit the scope of the invention to this particular structure. For example, the order of the n- and p-type layers of epitaxial structure 200 can be reversed as in structure 600 shown in FIG. 6. Structure 600 is comprised of substrate 601, buffer layer 602, transition layer 603, p-side cladding layer 604, transition layer 605, confinement layers 606 and 607, graded index layer 608, active region layers 609-611 where layer 610 is a quantum well, graded index layer 612, confinement layers 613 and 614, transition layer 615, n-side cladding layer 616, transition layer 617, and n-side contact layer 618.

It will also be understood that the detailed device structures described above were intended to simply demonstrate the benefits of the invention, i.e., using hybrid materials systems for n-side and p-side cladding layers, and that further improvements are possible through the optimization of the epitaxial and device structures. For example, the composition and thickness of the epitaxial layers can be varied within the ranges set forth above and the emitter width, front and rear facet reflectivities, cavity length, assembly techniques and test temperatures can all be further optimized.

It will also be understood by those skilled in the art that although the semiconductor laser described in the above embodiment employed a simple epitaxial structure, a diode laser can be fabricated with alternative structures while still using the hybrid materials systems for the n-cladding and p-cladding layers in accordance with the invention. For example, the active region of a device fabricated in accordance with the invention may comprise either a single or a multi quantum well structure so as to shift the laser emission wavelength and/or reduce the threshold current and slope efficiency. Alternative quantum well structures may also be easier to grow. The materials systems of the quantum well can be made from Al, In, Ga, As, P, Sb and/or N.

It will also be understood by those skilled in the art that although the semiconductor laser described in the above embodiment employed a simple, single emitter broad area structure, a diode laser can be fabricated with a more sophisticated structure while still using the hybrid materials systems for the n-cladding and p-cladding layers in accordance with the invention. For example, arrays can be produced with multiple single emitters monolithically integrated on a bar. Alternately, ridge confinement can be formed to produce single spatial mode lasers. Alternately, distributed feedback can be used to produce single longitudinal mode laser. Alternately, surface emitting lasers can be produced to achieve higher electrical to optical conversion efficiency.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A semiconductor diode laser, comprising:
a substrate;
an n-type buffer layer formed on the substrate;
an n-type cladding layer comprised of a first materials system formed on the n-type buffer layer, said first materials system having a first conduction band to valence band offset ratio;
a first confinement region formed on the n-type first cladding layer;
an active region formed on the first confinement layer;
a second confinement region formed on the active layer;
a p-type cladding layer comprised of a second materials system formed on the second confining layer, said second materials system having a second conduction band to valence band offset ratio, wherein said second conduction band to valence band offset ratio is larger than said first conduction band to valence band offset ratio; and
a p-type contact layer formed on the p-type cladding layer.

2. The semiconductor diode laser of claim 1, wherein said first materials system is selected from the group consisting of InGaP, AlGaInP and InGaAsP.

3. The semiconductor diode laser of claim 1, wherein said n-type cladding layer has a graded doping level.

4. The semiconductor diode laser of claim 1, wherein said n-type cladding layer has a constant doping level.

5. The semiconductor diode laser of claim 1, wherein said second materials system is comprised of AlGaAs with an Al content selected from the range of 5% to 100%.

6. The semiconductor diode laser of claim 1, wherein said substrate is selected from the group consisting of n-type GaAs, p-type GaAs, undoped GaAs, n-type InGaAs, p-type InGaAs and undoped InGaAs.

7. The semiconductor diode laser of claim 1, wherein said buffer layer is selected from the group consisting of GaAs and InGaAs.

8. The semiconductor diode laser of claim 1, wherein said active region contains a quantum well.

9. The semiconductor diode laser of claim 8, wherein said quantum well is comprised of InGaAs.

10. The semiconductor diode laser of claim 9, wherein said quantum well includes at least one material selected from the group consisting of Al, P, N and Sb.

11. The semiconductor diode laser of claim 1, wherein said active region contains a multi-quantum well structure.

12. The semiconductor diode laser of claim 11, wherein said multi-quantum well structure is comprised of InGaAs.

13. The semiconductor diode laser of claim 12, wherein said multi-quantum well structure includes at least one material selected from the group consisting of Al, P, N and Sb.

14. The semiconductor diode laser of claim 1, further comprising at least one barrier layer adjacent to at least a first side of said active region.

15. The semiconductor diode laser of claim 1, wherein said first confinement region is comprised of multiple layers.

16. The semiconductor diode laser of claim 1, wherein said first confinement region is comprised of at least one layer selected from the group consisting of AlGaAs layers and InGaAsP layers.

17. The semiconductor diode laser of claim 1, wherein said first confinement region includes at least one layer doped to a level of less than 3×10¹⁷ cm⁻³.

18. The semiconductor diode laser of claim 1, wherein said second confinement region is comprised of multiple layers.

19. The semiconductor diode laser of claim 1, wherein said second confinement region is comprised of at least one layer selected from the group consisting of AlGaAs layers and InGaAsP layers.

20. The semiconductor diode laser of claim 1, wherein said second confinement region includes at least one layer doped to a level of less than 3×10¹⁷ cm⁻³.

21. The semiconductor diode laser of claim 1, further comprising a transition layer interposed between said n-type buffer layer and said n-type cladding layer.

22. The semiconductor diode laser of claim 1, further comprising a transition layer interposed between said n-type cladding layer and said first confinement region.

23. The semiconductor diode laser of claim 1, further comprising a transition layer interposed between said second confinement region and said p-type cladding layer.

24. The semiconductor diode laser of claim 1, further comprising a transition layer interposed between said p-type cladding layer and said p-type contact layer.

25. The semiconductor diode laser of claim 1, further comprising a graded index layer interposed between said first confinement region and said active region.

26. The semiconductor diode laser of claim 1, further comprising a graded index layer interposed between said active region and said second confinement region.

27. The semiconductor diode laser of claim 1, wherein said semiconductor diode laser has an output wavelength in the range of 600 to 1600 nanometers.

28. The semiconductor diode laser of claim 1, wherein said semiconductor diode laser has an electrical to optical conversion efficiency of at least 60 percent.

29. The semiconductor diode laser of claim 1, wherein said semiconductor diode laser is selected from the group consisting of broad area lasers, linear array lasers, single spatial mode lasers, single longitudinal mode lasers and surface emitting lasers.

30. The semiconductor diode laser of claim 1, wherein said semiconductor diode laser is grown using an epitaxial growth technique selected from the group consisting of metal organic chemical vapor phase epitaxy, molecular beam epitaxy, gas source molecular beam epitaxy, chemical beam epitaxy, metal organic molecular beam epitaxy and liquid phase epitaxy.

31. A semiconductor diode laser, comprising:
a substrate;
a p-type buffer layer formed on the substrate;
a p-type cladding layer comprised of a first materials system formed on the p-type buffer layer, said first materials system having a first conduction band to valence band offset ratio;
a first confinement region formed on the p-type first cladding layer;
an active region formed on the first confinement layer;
a second confinement region formed on the active layer;
an n-type cladding layer comprised of a second materials system formed on the second confining layer, said second materials system having a second conduction band to valence band offset ratio, wherein said first conduction band to valence band offset ratio is larger than said second conduction band to valence band offset ratio; and
an n-type contact layer formed on the n-type cladding layer.

32. The semiconductor diode laser of claim 31, wherein said first materials system is comprised of AlGaAs with an Al content selected from the range of 5% to 100%.

33. The semiconductor diode laser of claim 31, wherein said second materials system is selected from the group consisting of InGaP, AlGaInP and InGaAsP.

34. The semiconductor diode laser of claim 31, wherein said substrate is selected from the group consisting of n-type GaAs, p-type GaAs, undoped GaAs, n-type InGaAs, p-type InGaAs and undoped InGaAs.

35. The semiconductor diode laser of claim 31, wherein said buffer layer is selected from the group consisting of GaAs and InGaAs.

36. The semiconductor diode laser of claim 31, wherein said active region contains a quantum well.

37. The semiconductor diode laser of claim 36, wherein said quantum well is comprised of InGaAs.

38. The semiconductor diode laser of claim 37, wherein said quantum well includes at least one material selected from the group consisting of Al, P, N and Sb.

39. The semiconductor diode laser of claim 31, wherein said active region contains a multi-quantum well structure.

40. The semiconductor diode laser of claim 39, wherein said multi-quantum well structure is comprised of InGaAs.

41. The semiconductor diode laser of claim 40, wherein said multi-quantum well structure includes at least one material selected from the group consisting of Al, P, N and Sb.

42. The semiconductor diode laser of claim 31, further comprising at least one barrier layer adjacent to at least a first side of said active region.

43. The semiconductor diode laser of claim 31, wherein said first confinement region is comprised of multiple layers.

44. The semiconductor diode laser of claim 31, wherein said first confinement region is comprised of at least one layer selected from the group consisting of AlGaAs layers and InGaAsP layers.

45. The semiconductor diode laser of claim 31, wherein said first confinement region includes at least one layer doped to a level of less than 3×10¹⁷ cm⁻³.

46. The semiconductor diode laser of claim 31, wherein said second confinement region is comprised of multiple layers.

47. The semiconductor diode laser of claim 31, wherein said second confinement region is comprised of at least one layer selected from the group consisting of AlGaAs layers and InGaAsP layers.

48. The semiconductor diode laser of claim 31, wherein said second confinement region includes at least one layer doped to a level of less than 3×10¹⁷ cm⁻³.

49. The semiconductor diode laser of claim 31, further comprising a transition layer interposed between said p-type buffer layer and said p-type cladding layer.

50. The semiconductor diode laser of claim 31, further comprising a transition layer interposed between said p-type cladding layer and said first confinement region.

51. The semiconductor diode laser of claim 31, further comprising a transition layer interposed between said second confinement region and said n-type cladding layer.

52. The semiconductor diode laser of claim 31, further comprising a transition layer interposed between said n-type cladding layer and said n-type contact layer.

53. The semiconductor diode laser of claim 31, further comprising a graded index layer interposed between said first confinement region and said active region.

54. The semiconductor diode laser of claim 31, further comprising a graded index layer interposed between said active region and said second confinement region.

55. The semiconductor diode laser of claim 31, wherein said semiconductor diode laser has an output wavelength in the range of 600 to 1600 nanometers.

56. The semiconductor diode laser of claim 31, wherein said semiconductor diode laser has an electrical to optical conversion efficiency of at least 60 percent.

57. The semiconductor diode laser of claim 31, wherein said semiconductor diode laser is selected from the group consisting of broad area lasers, linear array lasers, single spatial mode lasers, single longitudinal mode lasers and surface emitting lasers.

58. The semiconductor diode laser of claim 31, wherein said semiconductor diode laser is grown using an epitaxial growth technique selected from the group consisting of metal organic chemical vapor phase epitaxy, molecular beam epitaxy, gas source molecular beam epitaxy, chemical beam epitaxy, metal organic molecular beam epitaxy and liquid phase epitaxy.
